(19) United States
(12) Patent Application Publication
(10) Pub. No.: US 2013/0075881 A1
(43) Pub. Date: Mar. 28, 2013

(54) MEMORY CARD PACKAGE WITH A SMALL SUBSTRATE

(71) Applicants: Wan-Yu HUANG, Hukou Shiang (TW); Ting-Feng Su, Hukou Shiang (TW)

(72) Inventors: Wan-Yu HUANG, Hukou Shiang (TW); Ting-Feng Su, Hukou Shiang (TW)

(21) Appl. No.: 13/241,849

(22) Filed: Sep. 23, 2011

(51) Int. Cl. H01L 23/495

(52) U.S. Cl. 257/670; 257/E23.031

(57) ABSTRACT

Disclosed is a memory card package with a small substrate by using a metal die pad having an opening to substitute the chip-carrying function of a conventional substrate so that substrate dimension can be reduced. A substrate is attached under the metal die pad. A first chip is disposed on the substrate located inside the opening. A second chip is disposed on the metal die pad without covering the opening. A card-like encapsulant encapsulates the metal die pad, the top surface of the substrate, the first chip, and the second chip. The dimension of the substrate is smaller than the dimension of the encapsulant. The substrate has a lumpy sidewall encapsulated by the encapsulant so that the bottom surface of the substrate is coplanar with a bottom side of the encapsulant to increase the adhesion between the substrate and the encapsulant.

### FIELD OF THE INVENTION

The present invention relates to a semiconductor device, and more specifically to a memory card package with a small substrate.

### BACKGROUND OF THE INVENTION

Conventionally, a substrate with the same dimension as a memory card is implemented as a chip carrier in early memory packages such as revealed in U.S. Pat. No. 7,094,633 B2. A plurality of substrates are physically interconnected in a substrate strip, then chips are disposed on the corresponding substrates followed by molding the substrate strip, and finally, the molded substrate strip is singulated into individual memory cards. However, the singulated cut sides of the substrate are exposed from the encapsulant which cause poor moisture resistivity and poor reliability. Moreover, the substrate with the same dimension as the memory card is vulnerable for peeling due to stresses exerted on the peripheries of the memory card.

In order to reduce the packaging cost of memory packages, it has been attempted to replace a substrate by a leadframe as revealed in U.S. Pat. No. 7,488,620 B2. A leadframe provides leads and contact fingers. However, a leadframe is quite limited in circuitry layout with complicated wire bonding or long bonding wires where extra fabricated RDL may be needed on a chip surface leading to even higher chip fabrication cost.

### SUMMARY OF THE INVENTION

The main purpose of the present invention is to provide a memory card package with a small substrate to reduce substrate cost and to eliminate peeling or crack of a substrate from the memory card due to exerted stresses.

According to the present invention, a memory card package with a small substrate is revealed, primarily comprising a metal die pad with an opening, a substrate attached to a lower surface of the metal die pad, a first chip, at least a second chip, and a card-like encapsulant. The substrate has a top surface exposed from the opening where a plurality of contacting pads are disposed on a bottom surface of the substrate. The first chip is disposed on the substrate located inside the opening and the second chip is disposed on the metal die pad without covering the opening. The encapsulant encapsulates the metal die pad, the top surface of a substrate, the first chip, and the second chip. Moreover, the dimension of the substrate is smaller than the dimension of the encapsulant where the substrate has a lumpy sidewall encapsulated by the encapsulant so that the bottom surface of the substrate is coplanar with the bottom side of the encapsulant to increase the adhesion between the substrate and the encapsulant.

### DESCRIPTION OF THE DRAWINGS

FIG. 1 is a cross-sectional view of a memory card package with a small substrate according to the first embodiment of the present invention.

FIG. 2 is a perspective top view of the memory card package seeing through its encapsulant according to the first embodiment of the present invention.

FIG. 3 is a partially enlarged cross-sectional view of the memory card package illustrating one shape of the lumpy sidewall of the substrate according to the first embodiment of the present invention.

FIG. 4 is a partially enlarged cross-sectional view of memory card package illustrating another shape of the lumpy sidewall of the substrate according to the first various embodiment of the first embodiment of the present invention.

FIG. 5 is a top view of a substrate of memory card package illustrating another shape of the lumpy sidewall according to the second various embodiment of the first embodiment of the present invention.

FIG. 6 is a cross-sectional view of another memory card package with a small substrate according to the second embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

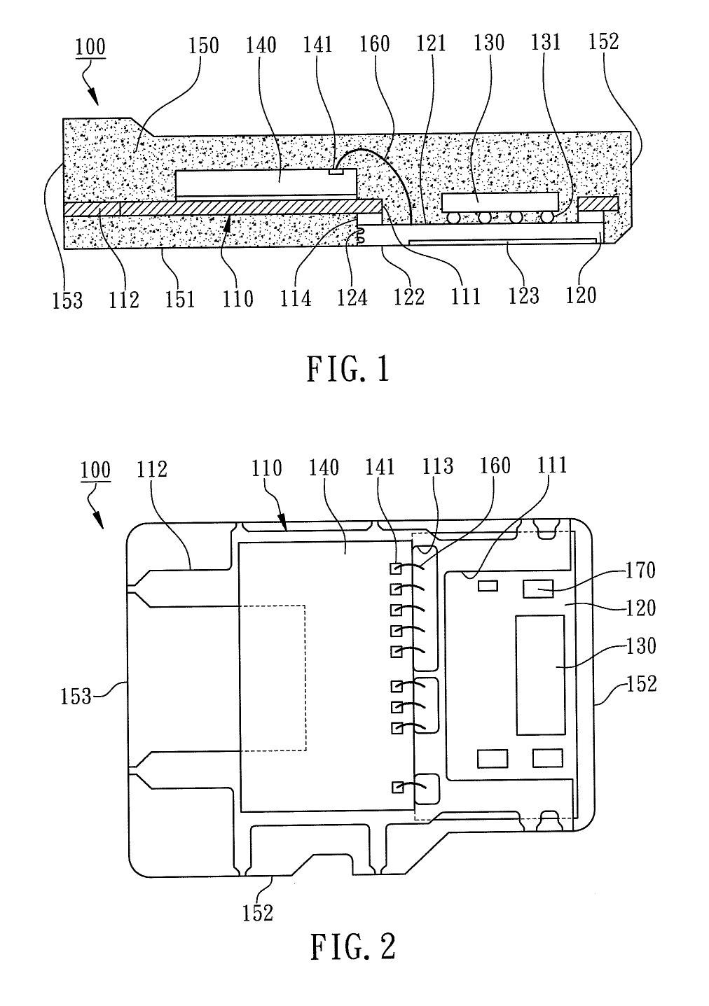

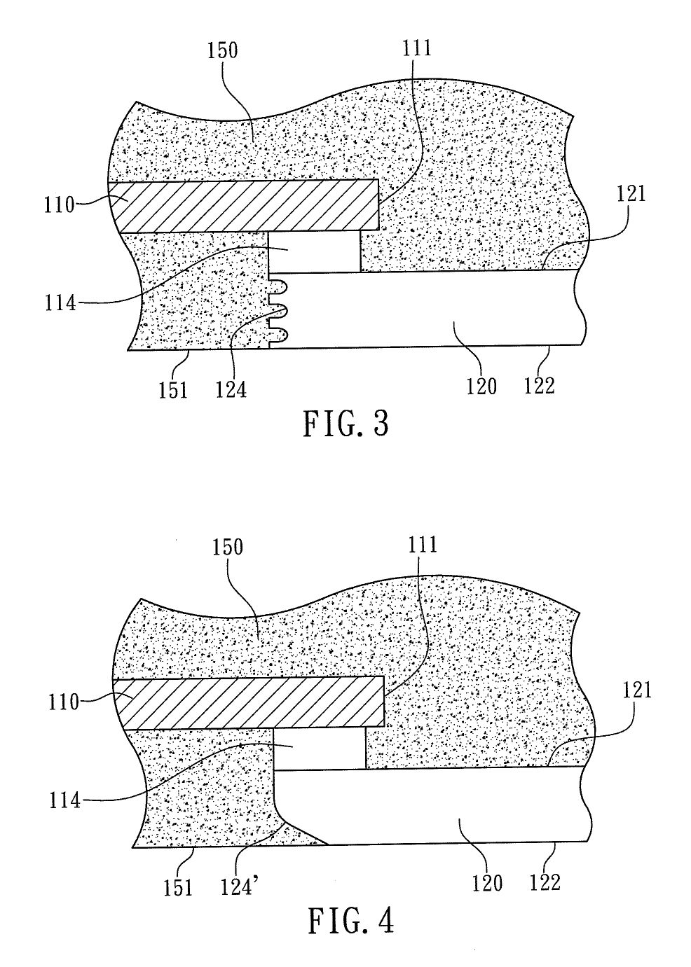

According to the first preferred embodiment of the present invention, a memory card package with a small substrate is revealed where a cross-sectional view is illustrated in FIG. 1, a perspective top view seeing through its encapsulant is illustrated in FIG. 2, and a partially enlarged cross-sectional view is illustrated in FIG. 3. The memory card package 100 primarily comprises a metal die pad 110 having an opening 111, a substrate 120, a first chip 130, at least a second chip 140, and a card-like encapsulant 150.

As shown in FIG. 1 and FIG. 2, the metal die pad 110 is made of metal like a conventional leadframe but without leads of a conventional leadframe. In the present embodiment, the peripheries of the metal die pad 110 are physically connected with a plurality of tie bars 112 extending to a plurality of non-plugging sides 153 of the encapsulant 150. Therefore, the tie bars 112 can physically secure a plurality of metal die pads 110 to form a metal chip carrier which can be completely molded in one single molding process for mass production. Preferably, the widths of the tie bars 112 are gradually shrunk toward the non-plugging sides 153 of the encapsulant 150 so that there is no singulated metal cut ends of the tie bars 112 exposed from the plugging sides 152 of the encapsulant 150 after singulation, moreover, the singulated metal cut ends of the tie bars 112 exposed from the non-plugging sides 152 of the encapsulant 150 have smaller cross-sections to avoid oxidation of large metal area leading to poor quality and poor reliability of memory card products.

As shown in FIG. 1 and FIG. 2, the substrate 120 has a top surface 121 exposed from the opening 111 and a bottom surface 122 with a plurality of contacting pads 123 disposed on the bottom surface 122. The substrate 120 is attached to a lower surface of the metal die pad 110 by an adhesive film 114 to adhere the peripheries of the top surface 121 of the substrate 120 to the lower surface of the metal die pad 110 around the opening 111. The contacting fingers 123 serve as the external terminals of the memory card package 100 where the surface finish of the contacting pads 123 may be plated gold. The substrate 120 has circuitry electrically connecting the top surface 121 and the bottom surface 122 such as BT or FR-4 printed circuit board or ceramic wiring substrate. The dimension of the substrate 120 is smaller than the dimension of the encapsulant 150. The “dimension” herein means the appearance observed from top or from bottom. For example, the peripheries of the top surface 121 of the substrate 120 is compared to the peripheries of the top side of the encapsulant 150 or the peripheries of the bottom surface 122 of the substrate is compared to the peripheries of the bottom side 151 of the encapsulant 150. In the present embodiment, the dimension of the bottom surface 122 of the substrate 120 is smaller than half of the dimension of the bottom side 151 of the encapsulant 150.

The first chip 130 is disposed on the top surface 121 of the substrate 120 located inside the opening 111 by either flip-chip bonding or by conventional die-attaching. In the present embodiment, the first chip 130 is electrically connected to the substrate 120 by a plurality of bumps 131 and further to the contacting pads 123. In a more specific embodiment, the memory card package 100 further comprises a plurality of passive components 170 such as resistors, inductors, or capacitors disposed on the top surface 121 of the substrate 120 located inside the opening 111. In the present embodiment, the first chip 130 is a controller chip.

The second chip 140 is attached to the metal die pad 110 without covering the opening 111. During packaging processes, the pre-cut substrate 120 with an appropriate dimension is attached to the metal die pad 110 followed by attaching the first chip 130 and the second chip 140, however, the sequence and numbers of the chips are not limited. In the present embodiment, the second chip 140 can be a memory chip such as NAND flash. In a more specific embodiment, the memory card package 100 further comprises a plurality of bonding wires 160 electrically connecting the bonding pads 141 of the second chip 140 to the top surface 121 of the substrate 120. Furthermore, as shown in FIG. 2, in the present embodiment, the opening 111 is a U-shaped opening so that the portion of the metal die pad 110 to carry part of the substrate 120 is a U-shaped supporting frame where the metal die pad 110 further has at least a wire-bonding slot 113 extended and parallel to both ends of the opening 111 to fully utilize the available space of the metal die pad 110 without damaging the structure of the metal die pad 110. Therein, the bonding wires 160 pass through the wire-bonding slot 113.

The encapsulant 150 encapsulates the metal die pad 110, the top surface 121 of the substrate 120, the first chip 130, and the second chip 140. The encapsulant 150 is a molding compound containing thermo-setting epoxy, organic filler, dyes, etc. In the present embodiment, the encapsulant 150 has an appearance of a memory card such as micro SD card as shown in FIG. 2. The contacting pads 123 are exposed from the bottom side 151 of the encapsulant 150 adjacent to the plugging side 151 of the encapsulant 150 where the rest of the sidewalls of the encapsulant 150 are non-plugging sides.

Furthermore, the substrate 120 has a lumpy sidewall 124 encapsulated by the encapsulant 150 to make the bottom surface 122 of the substrate 120 coplanar with the bottom side 151 of the encapsulant to increase the adhesion between the substrate 120 and the encapsulant 150 where the peripheries of the bottom surface 122 of the substrate 120 is encapsulated by the encapsulant 150 so that there is no exposed singulated cut sides of the substrate 120 at the plugging side nor at the non-plugging side of the encapsulant 150 to eliminate peeling or crack of the substrate 120 from the memory card due to exerted stresses. Preferably, the lumpy sidewalls 124 of the substrate 120 is away from the corresponding plugging side 152 of the encapsulant 150 to enhance the adhesion between the substrate 120 and the encapsulant 150 at the center of the memory card package 100 without the issues of peeling or crack of the substrate 120 from the memory card due to exerted stresses.

The shapes and the formation of the lumpy sidewall 124 have the following specific types and methods.

As shown in FIG. 3, in the present embodiment, the lumpy sidewall 124 of the substrate 120 has a reentrant cross-section looked like one or more grooves carved into the lumpy sidewalls 124 which can be formed by metal over-etching or by laser cutting on the lumpy sidewalls 124.

As shown in FIG. 4, a various embodiment of the present invention, the lumpy sidewall 124′ of the substrate 120 has a cross-section with a chambered gap adjacent to the bottom side 151 of the encapsulant 150. The chambered gap can be formed by cutting the bottom surface 122 with specific cutting tools with different widths or by an edge trimming process after substrate routing processes.

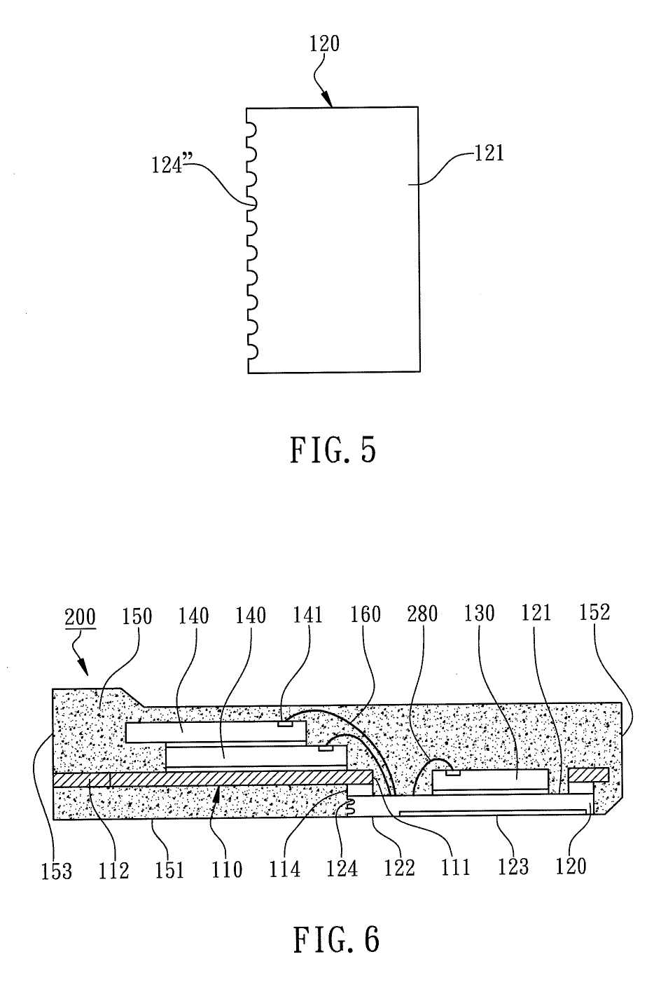

As shown in FIG. 5, another various embodiment of the present invention, the lumpy sidewall 124″ of the substrate 120 on the top surface 121 can be wavy formed by specific cutting tools or by drilling processes to drill holes with diameters larger than the width of the scribe lines before substrate routing processes.

The electrical connection between the substrate 120 and the chips and the number of chips are not limited in the present invention. As shown in FIG. 6, another memory card package 200 is revealed in the second embodiment of the present invention, primarily comprising a metal die pad 110 having an opening 111, a substrate 120 attached to the lower surface of the metal die pad 110, a first chip 130, a plurality of second chips 140, and an encapsulant 150 where the major components of the present embodiment are the same as the ones in the first preferred embodiment, therefore, the nomenclature with the corresponding designated numbers will be followed without further explanation. A plurality of second chips 140 are vertically stair-like stacked and a plurality of bonding wires 160 electrically connect the second chips 130 to the substrate 120. Additionally, a plurality of bonding wires 280 electrically connect the first chip 130 to the substrate 120

The substrate 120 has a top surface 121 exposed from the opening 111 and a bottom surface 122 with a plurality of contacting pads 123 disposed on the bottom surface 122. The first chip 130 is disposed on the substrate 120 located inside the opening 111 and the second chips 140 are disposed on the metal die pad 110 without covering the opening 111. The encapsulant 150 encapsulates the metal die pad 110, the top surface 121 of a substrate 120, the first chip 130, and the second chips 140. Moreover, the dimension of the substrate 120 is smaller than the dimension of the encapsulant 150 where the substrate 120 has a lumpy sidewall 124 encapsulated by the encapsulant 150 so that the bottom surface 122 of the substrate 120 is coplanar with the bottom side 151 of the encapsulant 150 to increase the adhesion between the substrate 120 and the encapsulant 150.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A memory card package comprising:
a metal die pad having an opening;
a substrate having a top surface attached to a lower surface of the metal die pad exposed from the opening and a bottom surface with a plurality of contacting pads disposed on the bottom surface;
a first chip disposed on the top surface of the substrate located inside the opening;
at least a second chip disposed on the metal die pad without covering the opening; and
a card-like encapsulant encapsulating the metal die pad, the top surface of the substrate, the first chip, and the second chip with the contacting pads exposed from a bottom side of the encapsulant; wherein the dimension of the substrate is smaller than the dimension of the encapsulant and the substrate has a lumpy sidewall encapsulated by the encapsulant so that the bottom surface of the substrate is coplanar with the bottom side of the encapsulant to increase the adhesion between the substrate and the encapsulant.

2. The memory card package as claimed in claim 1, wherein the lumpy sidewall of the substrate has a reentrant cross-section.

3. The memory card package as claimed in claim 1, wherein the lumpy sidewall of the substrate has a cross-section with a chambered gap adjacent to the bottom side of the encapsulant.

4. The memory card package as claimed in claim 1, wherein the lumpy sidewall of the substrate on the top surface is wavy.

5. The memory card package as claimed in claim 1, wherein the lumpy sidewall of the substrate is correspondingly away from a plugging side of the encapsulant.

6. The memory card package as claimed in claim 1, further comprising a plurality of tie bars physically connecting a plurality of peripheries of the metal die pad and extending to a plurality of non-plugging sides of the encapsulant.

7. The memory card package as claimed in claim 6, wherein the widths of the tie bars are gradually shrunk toward the non-plugging sides of the encapsulant.

8. The memory card package as claimed in claim 1, further comprising a plurality of bonding wires electrically connecting the second chip to the top surface of the substrate.

9. The memory card package as claimed in claim 8, wherein the opening is a U-shaped opening and the metal die pad further has at least a wire-bonding slot extended and parallel to both ends of the opening.

10. The memory card package as claimed in claim 1, further comprising a plurality of passive components disposed on the top surface of the substrate located inside the opening.
